(19) United States
(12) Patent Application Publication
(10) Pub. No.: US 2023/0063343 A1
(43) Pub. Date: Mar. 2, 2023

(54) MULTILEVEL PACKAGE SUBSTRATE DEVICE WITH BGA PIN OUT AND COAXIAL SIGNAL CONNECTIONS

(71) Applicant: Texas Instruments Incorporated, Dallas, TX (US)

(72) Inventors: Rajen Manicon Murugan, Dallas, TX (US); Yiqi Tang, Allen, TX (US); Jonathan Almeria Noquil, Plano, TX (US); Makarand Ramkrishna Kulkarni, Dallas, TX (US)

(73) Assignee: Texas Instruments Incorporated, Dallas, TX (US)

(21) Appl. No.: 17/410,535

(22) Filed: Aug. 24, 2021

(51) Int. Cl. H01L 23/498; H01L 23/00; H01L 23/538; H01L 21/56; H01L 21/48; H01L 21/60

(52) U.S. Cl. CPC H01L 23/49816; H01L 24/14; H01L 23/5386; H01L 23/5384; H01L 23/5385; H01L 21/56; H01L 21/4853; H01L 21/60; H01L 2021/60022

(57) ABSTRACT

An electronic device includes a multilevel package substrate with first and second levels extending in planes of first and second directions and spaced apart from one another along a third direction, the first level having a first side with landing areas and the second level having a second side with conductive landing pads. The electronic device includes a die with conductive terminals electrically coupled to respective ones of the landing areas, as well as solder balls attached to respective ones of the landing pads, and a package structure that encloses the die and a portion of the multilevel package substrate.

### BACKGROUND

Flip-chip ball grid array (FCBGA) packages and flip-chip chip scale packages (FCCSP) have benefits for electrical performance and solder joint reliability compared with provides better protection for chip and better solder joint reliability compared with direct chip attach (DCA) or chip on board (COB) approaches. However, FCBGA package designs cannot accommodate advanced circuit designs due to feature size tolerance limitations and existing printed circuit board (PCB) layouts may not be compatible with FCCSP package types.

### SUMMARY

In one aspect, an electronic device includes a multilevel package substrate has a first level and a second level, a die, solder balls, and a package structure. The first and second levels each have patterned conductive features and molded dielectric features. The first level extends in a plane of a first direction and an orthogonal second direction and includes a conductive first trace layer and a conductive first via layer. The first level has a first side with conductive landing areas spaced apart from one another along the first direction. The second level includes a conductive second trace layer and a conductive second via layer, with the second trace layer spaced apart from the first trace layer along a third direction that is orthogonal to the first and second directions. The second level has a second side with conductive landing pads. The die has conductive terminals electrically coupled to respective ones of the landing areas and the solder balls are attached to respective ones of the landing pads. The package structure encloses the die and a portion of the multilevel package substrate.

In another aspect, a multilevel package substrate includes a first level and a second level. The first and second levels each have patterned conductive features and molded dielectric features. The first level extends in a plane of a first direction and an orthogonal second direction. The first level includes a conductive first trace layer and a conductive first via layer. The first level has a first side with conductive landing areas spaced apart from one another along the first direction. The second level includes a conductive second trace layer and a conductive second via layer, and the second trace layer is spaced apart from the first trace layer along a third direction that is orthogonal to the first and second directions. The second level has a second side with conductive landing pads having circular shapes, and the landing pads include patterned conductive features of the second via layer.

In a further aspect, a method for fabricating an electronic device includes fabricating a multilevel package substrate with a first side having conductive landing areas and a second side having conductive landing pads, electrically coupling conductive terminals of a die to respective ones of the landing areas, enclosing the die and a portion of the multilevel package substrate in a package structure, and attaching solder balls to respective ones of the landing pads.

In yet another aspect, a multilevel package substrate includes a first level, a second level, and a coaxial connection formed in the first and second levels. The first and second levels each have patterned conductive features and molded dielectric features. The first level extends in a plane of a first direction and an orthogonal second direction. The first level includes a conductive first trace layer and a conductive first via layer. The first level has a first side with conductive landing areas spaced apart from one another along the first direction. The second level includes a conductive second trace layer and a conductive second via layer, and the second trace layer is spaced apart from the first trace layer along a third direction that is orthogonal to the first and second directions. The second level has a second side with conductive landing pads that include patterned conductive features of the second via layer.

### BRIEF DESCRIPTION OF THE DRAWINGS

FIG. 1 is a bottom perspective view of a packaged electronic device that includes a multilevel package substrate with BGA solder balls.

FIG. 1A is a partial sectional side elevation view of the electronic device taken along line 1A-1A in FIG. 1.

FIG. 2 is a flow diagram of a method for fabricating an electronic device.

FIGS. 3-16 are partial sectional side elevation views of the electronic device of FIG. 1 undergoing fabrication according to the method of FIG. 2.

FIGS. 17A-17D are simplified top views of example landing pads pattern arrangements in the multilevel package substrate.

FIG. 18 is a bottom perspective view of a packaged electronic device that includes a multilevel package substrate having coaxial connections and BGA solder balls.

FIG. 18A is a simplified perspective view of a coaxial connection having a cylindrical shield conductor that coaxially encircles a signal conductor in the multilevel package substrate of FIG. 18.

FIG. 18B is a simplified partial top view of a staggered landing pad pattern arrangement and the coaxial connection in the multilevel package substrate of FIG. 18.

FIG. 19 is a simplified partial top perspective view of another example coaxial connection having a number of cylindrical shield conductors that coaxially partially encircle or surround a signal conductor in another example multilevel package substrate.

FIG. 20 is a simplified partial top perspective view of another example coaxial connection having a number of arcuate shield conductors that coaxially partially encircle or surround a signal conductor in another example multilevel package substrate.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating.

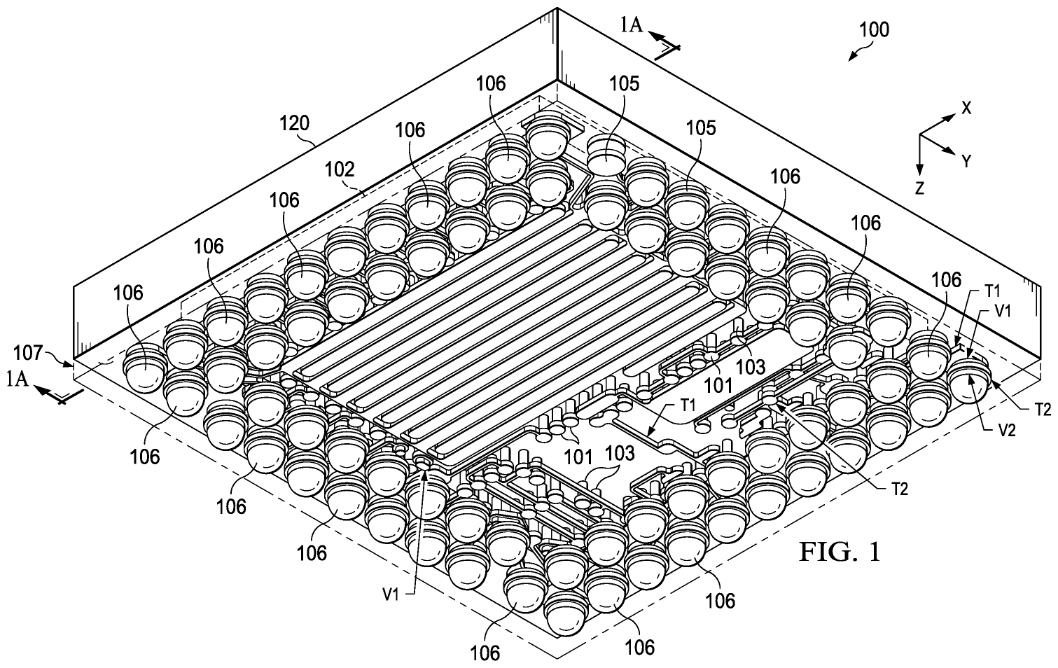

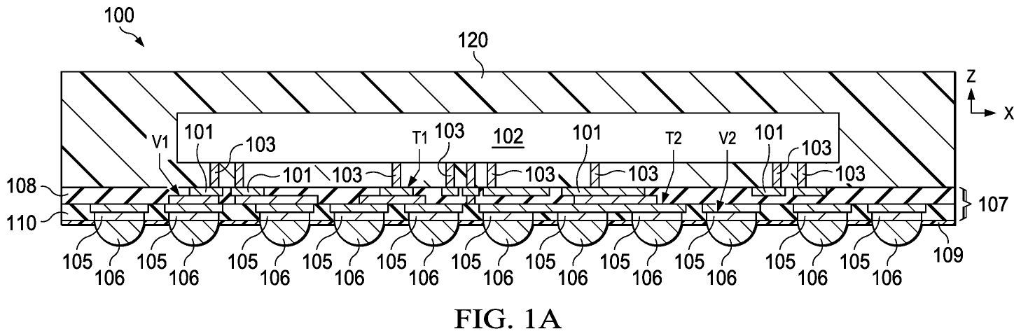

Referring initially to FIGS. 1 and 1A, FIG. 1 shows a perspective bottom view of a packaged electronic device 100 that includes a multilevel package substrate 107 and BGA solder balls 106. FIG. 1A shows a partial sectional side view of the electronic device 100 taken along line 1A-1A in FIG. 1. The electronic device 100 includes a semiconductor die 102 having electronic components therein, such as transistors, resistors, capacitors, etc. The die 102 has conductive terminals 103 that are electrically coupled by solder connections to respective conductive landing areas 101 of a first side of a multilevel package substrate 107. The solder balls 106 are coupled to conductive landing pads 105 of a second side of the multilevel package substrate 107.

The multilevel package substrate 107 has a first level that includes a first trace layer T1 and a first via layer V1, as well as a second level that includes a second trace layer T2 and a second via layer V2. In other examples, the multilevel package substrate includes more than two levels. The first and second levels T1, V1 and T2, V2 each have patterned conductive features, such as copper, aluminum, or other conductive metal. The first level T1, V1 includes compression molded dielectric features 108 and the second level T2, V2 includes compression molded dielectric features 110. The compression molded dielectric features 108 and 110 extend between different conductive features of the respective levels and between adjacent levels. The molded dielectric features 108 and 110 in one example are or include an electrically insulating dielectric material. The thickness and dielectric material in the respective levels provide a withstanding voltage according to a desired voltage separation between circuits and components thereof for a given design.

The first level T1, V1 extends in a plane of a first direction (e.g., labeled X in the drawings) and an orthogonal second direction (e.g., labeled Y). The first level T1, V1 includes a conductive first trace layer T1 and a conductive first via layer V1. The first level T1, V1 has a first side (e.g., the top side of the first trace layer T1) with the landing areas 101. The landing areas 101 are spaced apart from one another along the first direction X. The second level T2, V2 includes a conductive second trace layer T2 and a conductive second via layer V2. The second trace layer T2 is spaced apart from (e.g., below) the first trace layer T1 along a third direction (e.g., labeled Z) that is orthogonal to the first and second directions X and Y. The multilevel package substrate 107 includes a solder mask 109 on a portion of the second side between the conductive landing pads 105.

The electronic device 100 also includes a package structure 120 that encloses the die 102 and a portion of the multilevel package substrate 107. In one example, the package structure 120 is or includes a molded material, such as plastic. In another example, the package structure 120 is or includes a ceramic material. The solder balls 106 are attached to respective ones of the landing pads 105 and allow soldering of the electronic device 100 to a host system such as a printed circuit board (PCB). As shown in FIG. 1, the landing pads 105 have circular shapes and include patterned conductive features of the second via layer V2 to facilitate attachment of the solder balls 106 thereto. The electronic device 100 provides compatibility for existing PCB layouts design for FCBGA devices in combination with performance advantages associated with the multilevel package substrate 107. This facilitates improved electronic device performance without necessitating redesign of existing PCBs.

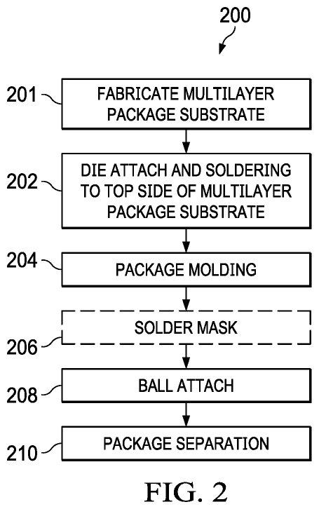

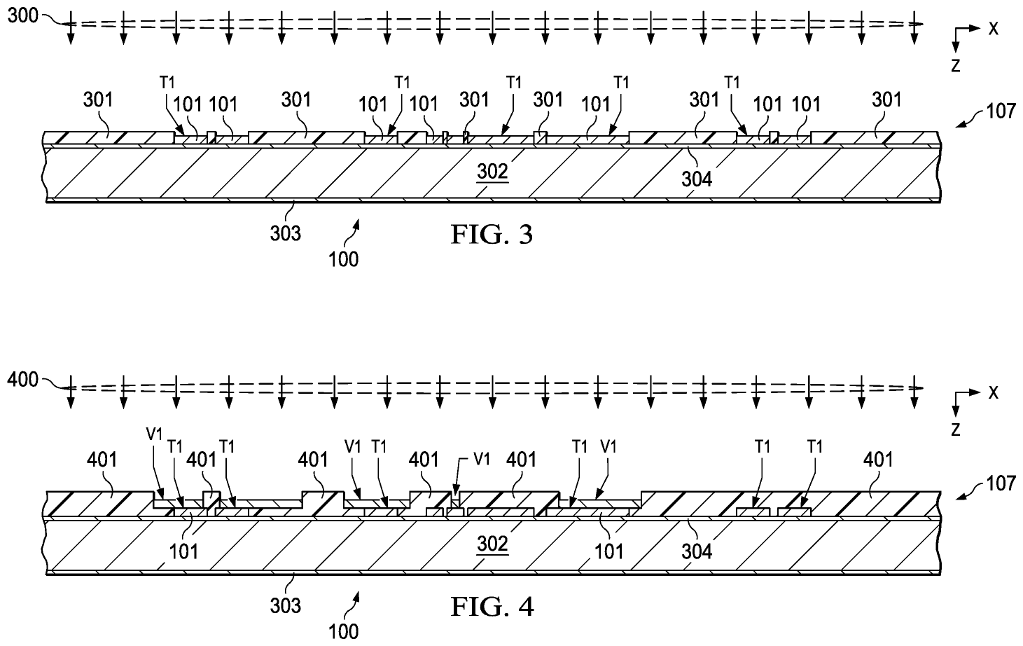

Referring also to FIGS. 2-16, FIG. 2 shows a method 200 for fabricating an electronic device, and FIGS. 3-16 show sectional side views of the electronic device 100 taken along line 1A-1A of FIG. 1 undergoing fabrication according to the method 200. At 201 in FIG. 2, the method 200 includes fabricating the multilevel package substrate 107, including fabricating the first level T1, V1 and fabricating the second level T2, V2. In one example, the multilevel package substrate fabrication at 201 includes forming the first level (e.g., T1, V1) on a carrier structure, and forming the second level (e.g., T2, V2) on the first level, after which the carrier structure is removed from the first level. The formation of the first and second levels in this example, concurrently forms the first side with the landing areas 101 spaced apart from one another along the first direction X and the second side with the circular conductive landing pads 105, which are defined in the illustrated implementation by the plating masks used in electroplating operations detailed below.

FIGS. 3-6 show formation of the first level T1, V1, for example, using an electroplating process 300 and a patterned plating mask 301. The illustrated example forms the first level having the first molded dielectric features 108. The first level formation starts with forming the first trace layer T1 using a stainless-steel carrier 302, such as a panel or strip with multiple prospective package substrate sections, one of which is shown in FIG. 3. The carrier structure 302 includes thin copper seed layers 303 and 304 on the respective bottom and top sides of the carrier structure 302 to facilitate the electroplating process 300. The electroplating process 300 deposits copper onto the upper seed layer 304 in the portions of the topside of the carrier structure that are exposed through the patterned plating mask 301. The mask 301 in this example includes circular openings that define the conductive landing areas 101 on the bottom side of the first trace layer T1, which forms a portion of the second side of the multilevel package substrate 107.

FIG. 4 shows the multilevel package substrate 107 after the process 300 is completed and the plating mask 301 has been removed. A second electroplating process 400 is performed in FIG. 4 using a patterned second plating mask 401 (e.g., a copper pillar plating process). The electroplating process 400 deposits further copper to form the first via layer V1 in the areas exposed by the second plating mask 401. After the process 400 is completed, the second plating mask 401 is removed.

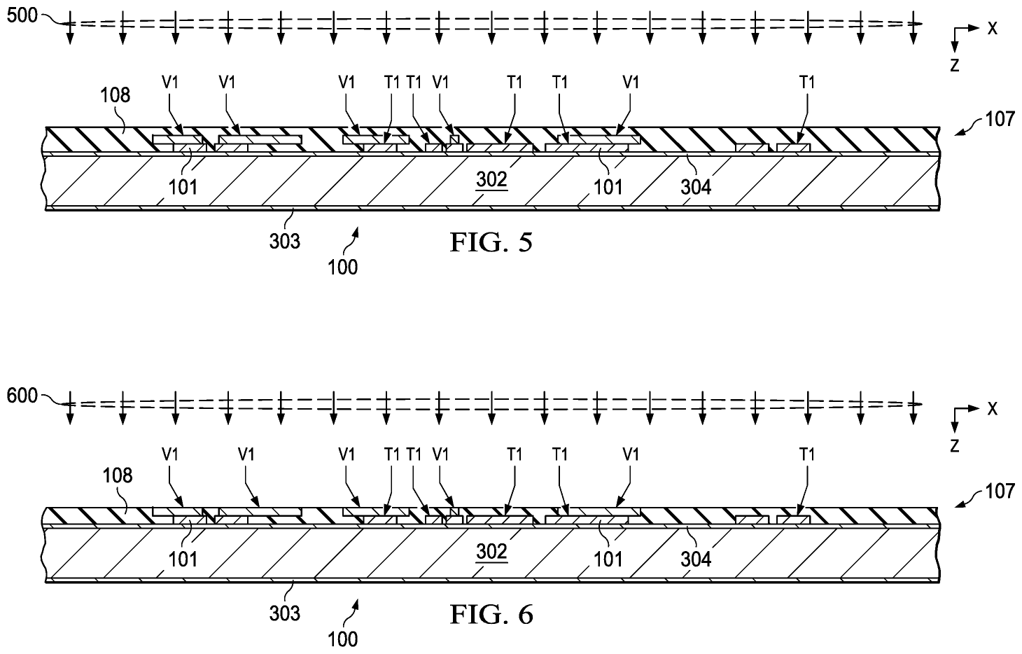

FIGS. 5 and 6 show the formation of the first molded dielectric features in the first level. A compression molding process 500 is performed in FIG. 5 that forms molded dielectric features 108 on exposed portions of the conductive features of the first trace layer T1 and the vias of the first via layer V1 to an initial thickness that covers the first trace layer T1 and the first via layer V1. A grinding process 600 is performed in FIG. 6, which grinds upper portions of the molded dielectric material 108 and exposes the upper portions of the first trace layer T1 and the first via layer V1. In another example, a chemical etch is used. In a further example, a chemical mechanical polishing process is used.

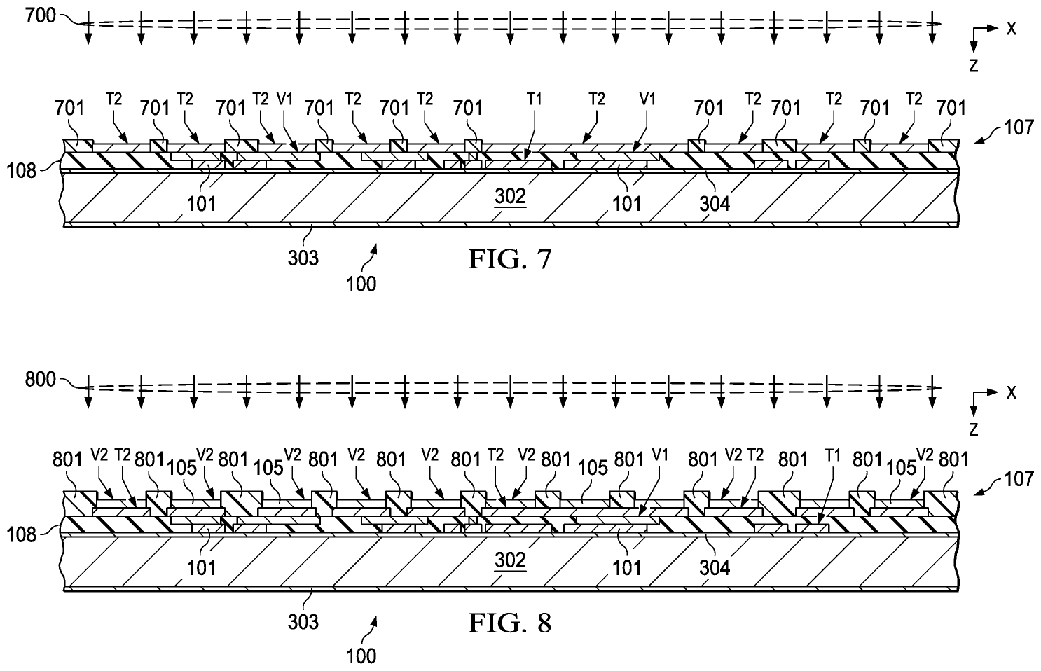

FIGS. 7-10 show formation of the second level of the multilevel package substrate 107, including forming the second trace layer T2, the second via layer V2, and the second molded dielectric features 110. In one example, the processing used to form the second level is similar to that used to form the first level, although not a requirement of all possible implementations. In the illustrated example, the second level processing forms the second level T2, V2 on the first level T1, V1, where the second level T2, V2 has the second side and the conductive landing pads 105 of a second side of the multilevel package substrate 107.

FIG. 7 shows the multilevel package substrate 107 undergoing an electroplating process 700 with a patterned plating mask 701. The electroplating process 700 deposits copper onto the top side of the portions of the finished first level that are exposed through the plating mask 701 to form the second trace layer. After the process 700 is completed, the plating mask 701 is removed. FIG. 8 shows the multilevel package substrate 107 undergoing another electroplating process 800 using another plating mask 801 (e.g., a copper pillar plating process). The electroplating process 800 deposits further copper to form the second via level V2 in the areas exposed by the plating mask 801. After the process 800 is completed, the plating mask 801 is removed. The finished second level forms the second side of the multilevel package substrate 107 including exposed sides of the conductive landing pads 105.

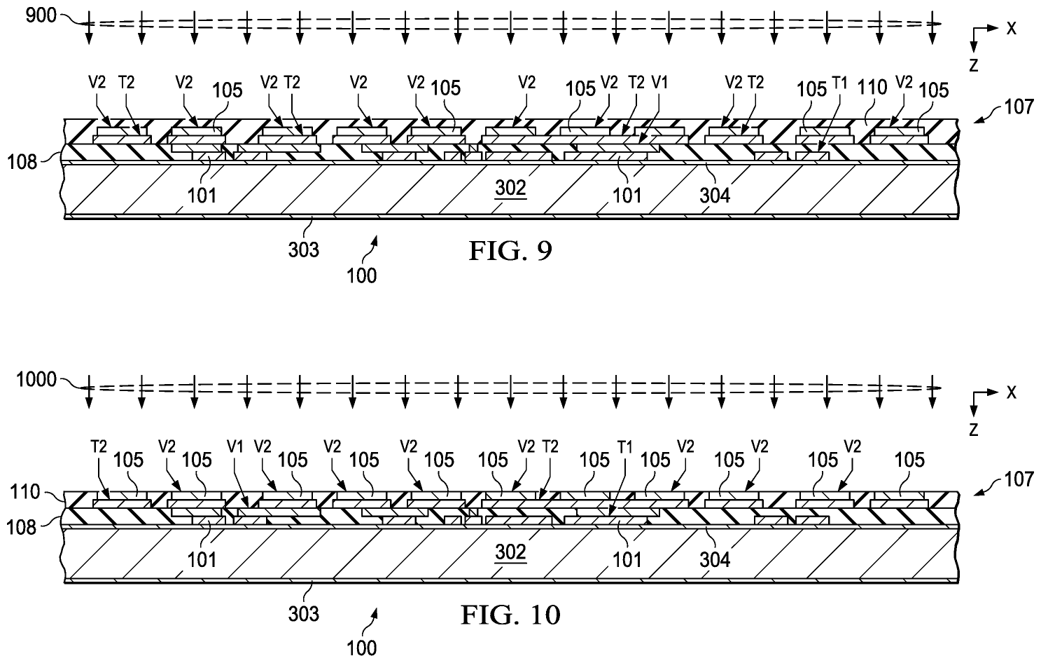

FIGS. 9 and 10 show formation of the second molded dielectric features in the second level using compression molding and grinding. A compression molding process 900 is performed in FIG. 9, which forms the molded dielectric features 110 on exposed portions of the second via layer V2 to an initial thickness that covers the second trace layer T2 and the second via layer V2. A grinding process 1000 is performed in FIG. 10, which grinds upper portions of the molded dielectric material 110 and exposes the sides of the conductive landing pads 105 of the second via layer V2. In another example, a chemical etch is used. In a further example, a chemical mechanical polishing process is used. In one example, the molded dielectric layers 108 and 110 of the multilevel package substrate 107 are or include MJ1 ABF RLF dielectric material, and the package structure 120 is or includes Carsem/TITL mold compound.

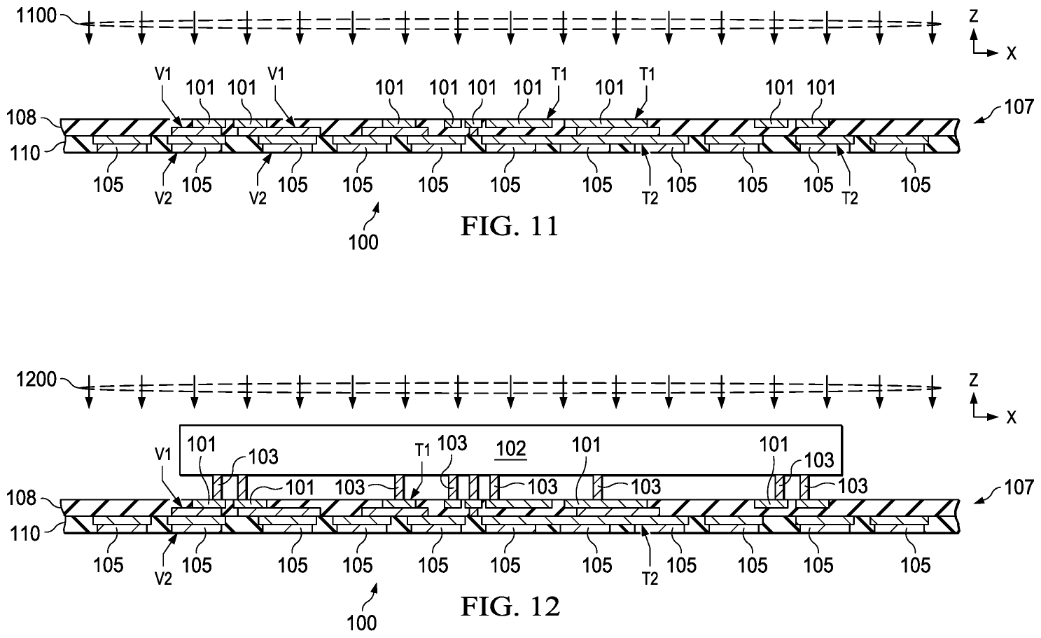

A process 1100 is performed in FIG. 11 that removes the carrier structure 302, 303, 304 from the first level T1, V1. In one example, a final chemical etch process is performed that removes any remnant copper of the carrier structure. This leaves the finished multilevel package substrate 107 as shown in FIG. 11.

The method 200 in FIG. 2 also includes die attach and soldering at 202 via an electrical connection process 1200 in FIG. 12 that electrically couples the conductive terminals 103 of the semiconductor die 102 to respective ones of the landing areas 101 on the top side of the first trace layer T1. The illustrated electrical connection example includes flip-chip soldering. In another implementation, the die 102 is attached to a portion of the first side of the multilevel package substrate 107, followed by a wire bonding process to electrically connect the die terminals 103 to respective the landing areas 101 on the top side of the first trace layer T1. In the example of FIG. 12, solder is applied (e.g., dipped or otherwise deposited) onto the bottom sides of the conductive terminals 103 of the semiconductor die 102, and the semiconductor die 102 is placed with the respective terminals 103 on or over the respective landing areas 101 of the first trace layer T1. A thermal solder reflow process 1200 is performed that solders the die terminals 103 to the landing areas 101.

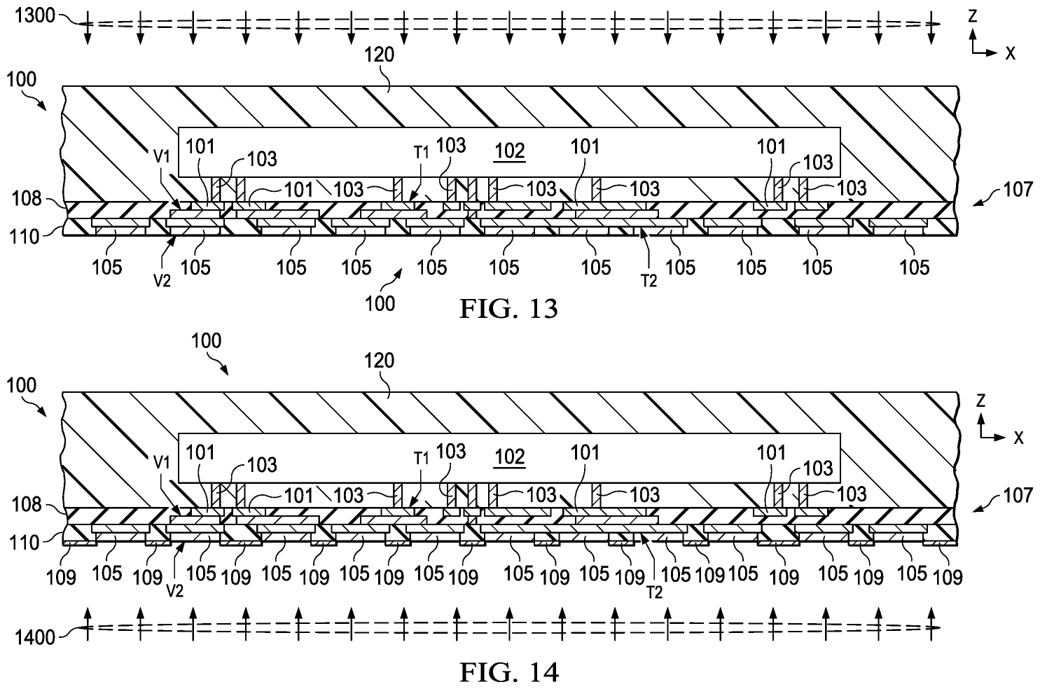

The method 200 continues at 204 in FIG. 2 with package molding. FIG. 13 shows one example, in which a molding process 1300 is performed that encloses a portion of the multilevel package substrate 107 and the die 102 in the package structure 120.

In one example, the method 200 includes forming the solder mask 109 at 206 on a portion of the second side between the conductive landing pads 105. FIG. 14 shows one example, in which a solder mask printing process 1400 is performed at 206. The process 1400 prints the solder mask material 109 onto select portions of the second side of the multilevel package substrate 107 between the conductive landing pads 105, as shown in FIG. 14. In another implementation, the process 1400 is performed to print the solder mask material 109 partially onto edge portions of the conductive landing pads 105. In another implementation, no solder mask is formed.

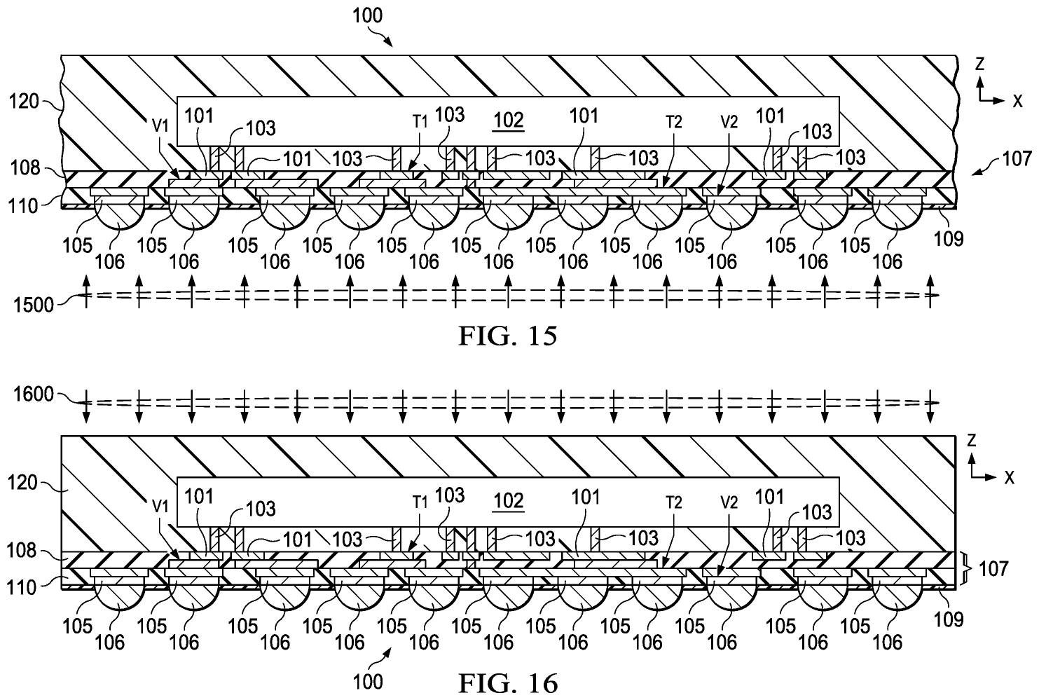

At 208 in FIG. 2, a ball attach process is performed. FIG. 15 shows one example, in which a ball attach process 1500 is performed that attaches the solder balls 106 to the conductive landing pads 105 on the second side of the multilevel package substrate 107.

A package separation process (not shown) is then performed at 208 in FIG. 2, such as sawing, laser cutting, etc. FIG. 16 shows one example, in which a package separation process 1600 is performed that separates individual packaged electronic devices 100 from a panel of concurrently processed devices, where FIGS. 1 and 1A above shows the example finished electronic device 100. In another example, the ball attach process at 208 is omitted, and the exposed bottom sides of the conductive landing pads 105 of the second via layer V2 can be soldered to a host PCB using solder paste, or installed in a socket of a host PCB, or connected by other suitable attachment techniques, for example, in a land grid array (LGA) application. In another implementation, solder pads (not shown) are attached to the conductive landing pads 105 on the second side of the multilevel package substrate 107 (e.g., at 208 in FIG. 2) instead of attaching solder balls, to facilitate later soldering to a host PCB or attachment to a socket (not shown) of a host PCB.

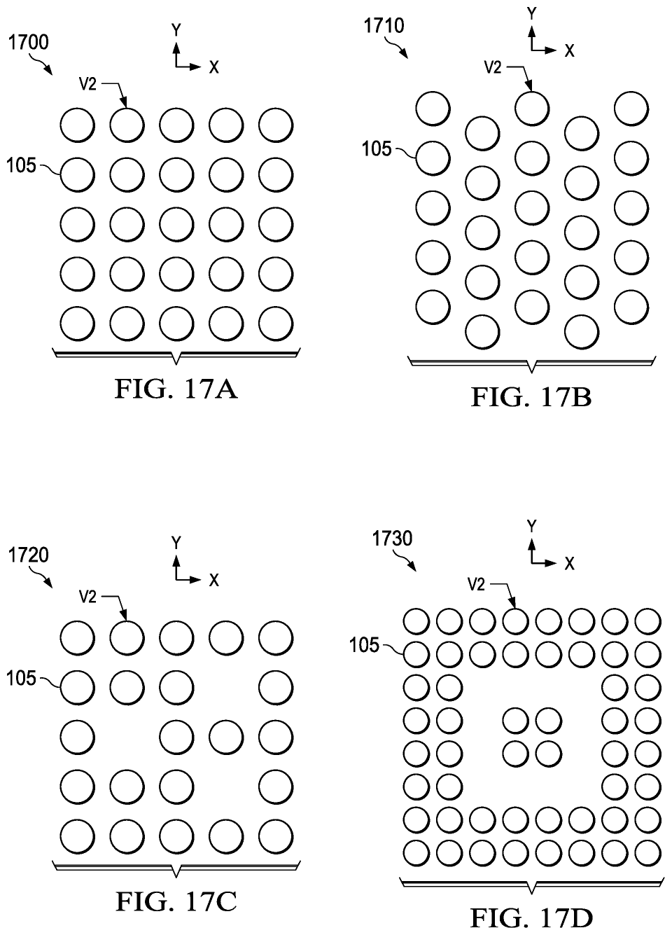

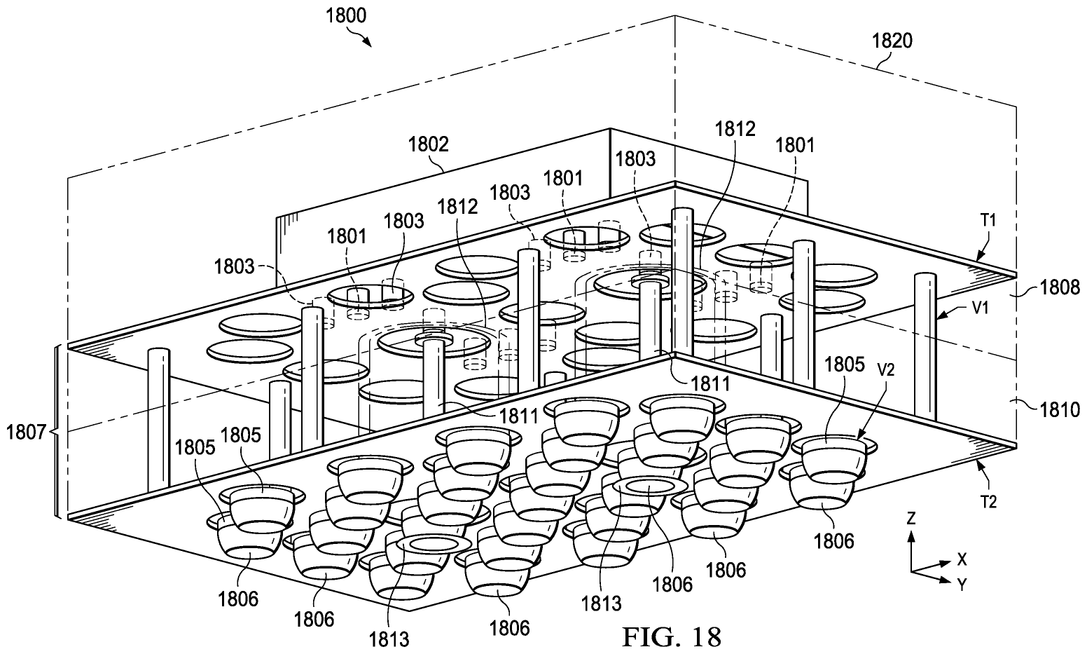

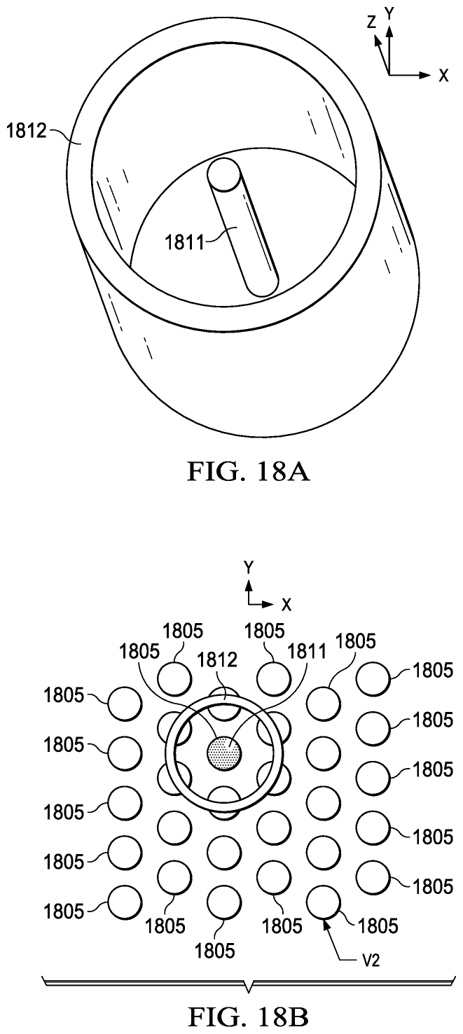

FIGS. 17A-17D show example landing pad pattern arrangements in the multilevel package substrate. FIG. 17A shows a first example patterned 1700 including exposed sides of the conductive landing pads 105 of the second via layer V2 arranged in fully populated and aligned rows and columns. FIG. 17B shows a second example, in which the landing pads 105 are arranged in a staggered pattern 1710 having columns along the second direction Y, where adjacent columns of the pattern 1710 are staggered relative to one another along the second direction Y. An example implementation of the pattern 1700 is illustrated in another example electronic device illustrated and described below in connection with FIGS. 18-18B. FIGS. 17C and 17D show respective patterned 1720 and 1730 with depopulated positions within an array format of rows and columns along the respective capital X and Y directions. The patterns 1720 and 1730 in these examples have rows of the landing pads 105 positioned along the first direction X and columns of the landing pads 105 positioned along the second direction Y, in which one or more locations of the array pattern 1710 have no landing pad 105.

Referring also to FIGS. 18-18B, FIG. 18 shows a packaged electronic device 1800 with a multilevel package substrate 1807 having coaxial connections 1811, 1812 and BGA solder balls 1806 electrically coupled to respective landing pads 1805 arranged in a staggered pattern. FIG. 18A shows a coaxial connection 1811, 1812 having a cylindrical shield conductor 1812 that coaxially encircles a signal conductor 1811 in the multilevel package substrate 1807 of FIG. 18. FIG. 18B shows a partial top view of the staggered landing pad pattern arrangement (e.g., similar to the pattern 1710 in FIG. 17B above), in which the coaxial connection 1811, 1812 is positioned for electrical connection with certain of the landing pads 1805 in the multilevel package substrate 1807. In the example of FIGS. 18-18B, the landing pads 1805 are arranged in a staggered pattern having columns along the second direction Y and adjacent columns of the pattern are staggered relative to one another along the second direction Y.

The electronic device 1800 in FIGS. 18-18B includes a semiconductor die 1802 having electronic components therein, such as transistors, resistors, capacitors, etc. The die 1802 has conductive terminals 1803 that are electrically coupled by solder connections to respective conductive landing areas 1801 of a first side of a multilevel package substrate 1807. The illustrated example is a flip-chip implementation, in which the semiconductor die 1802 is flip-chip soldered to the landing areas 1801 of the multilevel package substrate 1807. In another implementation, epoxy or other die attachment is used and bond wires (not shown) are used to form electrical connections between terminals of the die and conductive features of the multilevel package substrate. The solder balls 1806 are coupled to conductive landing pads 1805 of a second side of the multilevel package substrate 1807, which can be soldered to a host printed circuit board (not shown).

The multilevel package substrate 1807 in this example is a two-level structure. In other implementations, three or more levels can be provided. The multilevel package substrate 1807 has a first level that includes a first trace layer T1 and a first via layer V1, as well as a second level that includes a second trace layer T2 and a second via layer V2. In other examples, the multilevel package substrate includes more than two levels. The first and second levels T1, V1 and T2, V2 each have patterned conductive features, such as copper, aluminum, or other conductive metal. The first level T1, V1 includes compression molded dielectric features 1808 and the second level T2, V2 includes compression molded dielectric features 1810. The compression molded dielectric features 1808 and 1810 extend between different conductive features of the respective levels and between adjacent levels. The molded dielectric features 1808 and 1810 in one example are or include an electrically insulating dielectric material, such as MJ1 ABF RLF dielectric material. The thickness and dielectric material 1808 and 1810 in the respective levels provide a withstanding voltage according to a desired voltage separation between circuits and components thereof for a given design.

The first level T1, V1 extends in a plane of a first direction (e.g., labeled X in the drawings) and an orthogonal second direction (e.g., labeled Y). The first level T1, V1 includes a conductive first trace layer T1 and a conductive first via layer V1. The first level T1, V1 has a first side (e.g., the top side of the first trace layer T1) with the landing areas 1801. The landing areas 1801 are spaced apart from one another along the first direction X. The second level T2, V2 includes a conductive second trace layer T2 and a conductive second via layer V2. The second trace layer T2 is spaced apart from (e.g., below) the first trace layer T1 along a third direction (e.g., labeled Z) that is orthogonal to the first and second directions X and Y. The multilevel package substrate 1807 in one example includes a solder mask on a portion of the second side between the conductive landing pads 1805. In other examples, the solder mask is omitted.

The electronic device 1800 also includes a package structure 1820 that encloses the die 1802 and a portion of the multilevel package substrate 1807. In one example, the package structure 1820 is or includes a molded material, such as Carsem/TITL mold compound or other plastic. In another example, the package structure 1820 is or includes a ceramic material. The solder balls 1806 are attached to respective ones of the landing pads 1805 and allow soldering of the electronic device 1800 to a host system such as a printed circuit board (PCB). As shown in FIG. 18, the landing pads 1805 have circular shapes and include patterned conductive features of the second via layer V2 to facilitate attachment of the solder balls 1806 thereto.

The multilevel package substrate 1807 in this example includes a coaxial connection having a conductive signal conductor 1811 and a conductive shield conductor 1812. The shield conductor 1812 The conductive signal conductor 1811 extends along the third direction Z from a first one of the landing areas 1801 of the first level T1, V1 to a first one of the landing pads 1805 of the second level. The conductive signal conductor 1811 in one example has a cylindrical shape and includes conductive portions in the first trace layer T1, the first via layer V1, the second trace layer T2, and the second via layer V2. Other shapes can be used in other implementations. The conductive shield conductor 1812 in this example is a conductive cylinder that extends along the third direction Z from at least a second one of the landing areas 1801 of the first level T1 to one or more second landing pads 1805 of the second level. As best shown in FIG. 18B, the staggered landing pad pattern (e.g., like the pattern 1710 in FIG. 17B above allows connection of the cylindrical shield conductor 1812 to six of the landing pads 1805.

In one implementation, the first trace layer T1 includes a ground plane to which the cylindrical shield conductor 1812 is attached, to provide a grounded shield that is radially spaced from and surrounds the conductive signal conductor 1811 within the multilevel package substrate 1807. The conductive shield conductor 1812 is spaced apart from the conductive signal conductor 1811 along the first and second directions X, Y. In the illustrated example, the shield conductor 1812 coaxially encircles (e.g., surrounds) the signal conductor 1811, and the landing pads 1805 that are connected to the shield conductor 1812 are radially spaced apart from the landing pad 1805 that is connected to the signal conductor 1811 by equal distances. As indicated in FIG. 18B, the staggered pattern of the landing pads 1805 facilitates equal spacing of the landing pads 1805, with any three proximate landing pads 1805 forming an equilateral triangle in the X-Y plane.

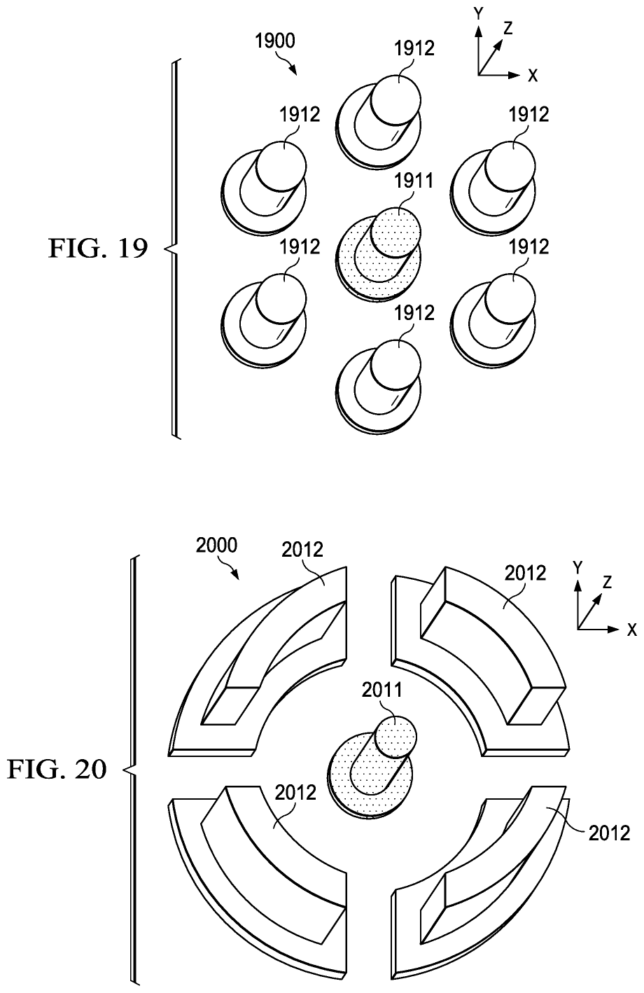

FIG. 19 shows another example coaxial connection configuration 1900 in another multilevel package substrate implementation, in which multiple (e.g., 6) cylindrical shield conductors 1912 that coaxially partially encircle or surround a signal conductor 1911. In this example, the conductive signal conductor 1911 has a cylindrical shape and includes conductive portions in the first trace layer T1, the first via layer V1, the second trace layer T2, and the second via layer V2. Other shapes can be used in other implementations (e.g., FIG. 20 below).

The conductive shield conductor 1912 in this example includes six cylindrical portions that individually extend along the third direction Z from one of the landing areas of the first level T1 to a respective landing pad of the second level, and the cylindrical shield conductors 1912 provide partial encirclement of the signal conductor 1911. In the illustrated implementation, moreover, the alignment of the signal conductor 1911 and the individual shield conductor portions 1912 with the associated landing pads in the staggered pattern (e.g., pattern 1710 in FIG. 17B above) provide substantially equal spacing between the signal conductor 1911 and the individual shield conductor portions 1912 in the multilevel package substrate.

FIG. 20 shows another coaxial connection 2000 having a number of arcuate shield conductors 2012 that coaxially partially encircle or surround a signal conductor 2011 in another example multilevel package substrate. In this example, for arcuate shield conductors 1912 coaxially partially encircle or surround the signal conductor 2011. As in the above examples, the conductive signal conductor 2011 has a cylindrical shape and includes conductive portions in the first trace layer T1, the first via layer V1, the second trace layer T2, and the second via layer V2. Other shapes can be used in other implementations. The arcuate sections of the shield conductor 1912 are spaced apart from the conductive signal conductor 2011, and each shield section 2012 extends along the third direction Z from a respective one or more of the landing areas of the first level T1, V1 to a respective one or group of the landing pads of the second level. In the example of FIG. 20, the arcuate shield conductor portions 2012 coaxially partially encircle or surround the signal conductor 2011.

The described solutions provide multilevel package substrate structures with routable conductive features and molded dielectric material in combination with BGA solder balls to facilitate adaptation of circuitry in packaged electronic devices for high speed and high frequency applications such as radio frequency (RF) amplifiers, high-speed multipliers, etc. while providing pin-compatibility for use in existing printed circuit board design layouts to allow substitution of improved electronic devices having reduced cost and improved performance for earlier devices having BGA package formats. These advantages facilitate conversion of electronic circuits previously packaged in flip chip ball grid array (FC-BGA) or FCCSP packages. Described examples also provide coaxial signal coupling with staggered landing pad pattern arrangements in multilevel package substrate implementations to further enhance high-frequency circuit performance in packaged electronic devices.

Modifications are possible in the described examples, and other implementations are possible, within the scope of the claims.

What is claimed is:

1. An electronic device, comprising:
a multilevel package substrate having a first level and a second level, the first and second levels each having patterned conductive features and molded dielectric features;
the first level extending in a plane of a first direction and an orthogonal second direction, the first level including a conductive first trace layer and a conductive first via layer, the first level having a first side with conductive landing areas spaced apart from one another along the first direction;
the second level including a conductive second trace layer and a conductive second via layer, the second trace layer spaced apart from the first trace layer along a third direction that is orthogonal to the first and second directions, the second level having a second side with conductive landing pads;
a die having conductive terminals electrically coupled to respective ones of the landing areas;
solder balls attached to respective ones of the landing pads; and
a package structure that encloses the die and a portion of the multilevel package substrate.

2. The electronic device of claim 1, wherein the landing pads have circular shapes and include patterned conductive features of the second via layer.

3. The electronic device of claim 2, wherein:
the landing pads are arranged in a pattern having columns along the second direction; and
adjacent columns of the pattern are staggered relative to one another along the second direction.

4. The electronic device of claim 3, wherein:
the multilevel package substrate includes a coaxial connection having a conductive signal conductor and a conductive shield conductor;
the conductive signal conductor extending along the third direction from a first one of the landing areas of the first level to a first one of the landing pads of the second level, the conductive signal conductor including conductive portions in the first trace layer, the first via layer, the second trace layer, and the second via layer;
the conductive shield conductor extending along the third direction from a second one of the landing areas of the first level to a second one of the landing pads of the second level;
the conductive shield conductor spaced apart from the conductive signal conductor along the first and second directions; and
the conductive shield conductor at least partially coaxially encircling the conductive signal conductor.

5. The electronic device of claim 4, wherein the conductive shield conductor has a cylindrical shape that coaxially encircles the conductive signal conductor.

6. The electronic device of claim 4, wherein the conductive shield conductor includes multiple sections spaced apart from the conductive signal conductor, each section extending along the third direction from a respective one of the landing areas of the first level to a respective one of the landing pads of the second level.

7. The electronic device of claim 2, wherein:
the landing pads are arranged in a pattern having rows along the first direction and columns along the second direction; and
a location of the pattern has no landing pad.

8. The electronic device of claim 1, wherein:
the landing pads are arranged in a pattern having columns along the second direction; and
adjacent columns of the pattern are staggered relative to one another along the second direction.

9. The electronic device of claim 8, wherein:
the multilevel package substrate includes a coaxial connection having a conductive signal conductor and a conductive shield conductor;
the conductive signal conductor extending along the third direction from a first one of the landing areas of the first level to a first one of the landing pads of the second level, the conductive signal conductor including conductive portions in the first trace layer, the first via layer, the second trace layer, and the second via layer;
the conductive shield conductor extending along the third direction from a second one of the landing areas of the first level to a second one of the landing pads of the second level;
the conductive shield conductor spaced apart from the conductive signal conductor along the first and second directions; and
the conductive shield conductor at least partially coaxially encircling the conductive signal conductor.

10. The electronic device of claim 1, wherein:
the landing pads are arranged in a pattern having rows along the first direction and columns along the second direction; and
a location of the pattern has no landing pad.

11. A multilevel package substrate, comprising a first level; and a second level, the first and second levels each having patterned conductive features and molded dielectric features;
the first level extending in a plane of a first direction and an orthogonal second direction, the first level including a conductive first trace layer and a conductive first via layer, the first level having a first side with conductive landing areas spaced apart from one another along the first direction;
the second level including a conductive second trace layer and a conductive second via layer, the second trace layer spaced apart from the first trace layer along a third direction that is orthogonal to the first and second directions, the second level having a second side with conductive landing pads, the landing pads having circular shapes, and the landing pads including patterned conductive features of the second via layer.

12. The multilevel package substrate of claim 11, wherein:
the landing pads are arranged in a pattern having columns along the second direction; and
adjacent columns of the pattern are staggered relative to one another along the second direction.

13. The multilevel package substrate of claim 12, wherein:
the multilevel package substrate includes a coaxial connection having a conductive signal conductor and a conductive shield conductor;
the conductive signal conductor extending along the third direction from a first one of the landing areas of the first level to a first one of the landing pads of the second level, the conductive signal conductor including conductive portions in the first trace layer, the first via layer, the second trace layer, and the second via layer;
the conductive shield conductor extending along the third direction from a second one of the landing areas of the first level to a second one of the landing pads of the second level;
the conductive shield conductor spaced apart from the conductive signal conductor along the first and second directions; and
the conductive shield conductor at least partially coaxially encircling the conductive signal conductor.

14. The multilevel package substrate of claim 13, wherein the conductive shield conductor has a cylindrical shape that coaxially encircles the conductive signal conductor.

15. The multilevel package substrate of claim 13, wherein the conductive shield conductor includes multiple sections spaced apart from the conductive signal conductor, each section extending along the third direction from a respective one of the landing areas of the first level to a respective one of the landing pads of the second level.

16. The multilevel package substrate of claim 11, wherein:
the landing pads are arranged in a pattern having rows along the first direction and columns along the second direction; and
a location of the pattern has no landing pad.

17. A method for fabricating an electronic device, the method comprising:
fabricating a multilevel package substrate, including:
forming a first level on a carrier structure, the first level having first patterned conductive features and first molded dielectric features, the first level extending in a plane of a first direction and an orthogonal second direction, the first level including a conductive first trace layer and a conductive first via layer, the first level having a first side with landing areas spaced apart from one another along the first direction;
forming a second level on the first level, the second level having second patterned conductive features and second molded dielectric features, the second level including a conductive second trace layer and a conductive second via layer, the second trace layer spaced apart from the first trace layer along a third direction that is orthogonal to the first and second directions, the second level having a second side with conductive landing pads; and
removing the carrier structure from the first level;
performing an electrical connection process that electrically couples conductive terminals of a die to respective ones of the landing areas;
performing a molding process that encloses the die and a portion of the multilevel package substrate in a package structure; and
attaching solder balls to respective ones of the landing pads.

18. The method of claim 17, further comprising:
forming a solder mask on a portion of the second side between the conductive landing pads.

19. The method of claim 17, wherein performing the electrical connection process includes wirebonding the conductive terminals of the die to the respective ones of the landing areas.

20. The method of claim 17, wherein performing the electrical connection process includes flip-chip soldering the conductive terminals of the die to the respective ones of the landing areas.

21. A multilevel package substrate, comprising a first level; a second level; and a coaxial connection, the first and second levels each having patterned conductive features and molded dielectric features;
the first level extending in a plane of a first direction and an orthogonal second direction, the first level including a conductive first trace layer and a conductive first via layer, the first level having a first side with conductive landing areas spaced apart from one another along the first direction;
the second level including a conductive second trace layer and a conductive second via layer, the second trace layer spaced apart from the first trace layer along a third direction that is orthogonal to the first and second directions, the second level having a second side with conductive landing pads, and the landing pads including patterned conductive features of the second via layer;
the coaxial connection having a conductive signal conductor and a conductive shield conductor;
the conductive signal conductor extending along the third direction from a first one of the landing areas of the first level to a first one of the landing pads of the second level, the conductive signal conductor including conductive portions in the first trace layer, the first via layer, the second trace layer, and the second via layer;
the conductive shield conductor extending along the third direction from a second one of the landing areas of the first level to a second one of the landing pads of the second level;
the conductive shield conductor spaced apart from the conductive signal conductor along the first and second directions; and
the conductive shield conductor at least partially coaxially encircling the conductive signal conductor.

22. The multilevel package substrate of claim 21, wherein:
the landing pads are arranged in a pattern having columns along the second direction; and
adjacent columns of the pattern are staggered relative to one another along the second direction.

23. The multilevel package substrate of claim 21, wherein the conductive shield conductor has a cylindrical shape that coaxially encircles the conductive signal conductor.

24. The multilevel package substrate of claim 21, wherein the conductive shield conductor includes multiple sections spaced apart from the conductive signal conductor, each section extending along the third direction from a respective one of the landing areas of the first level to a respective one of the landing pads of the second level.
